(19) United States
(12) Patent Application Publication
(10) Pub. No.: US 2025/0132222 A1
(43) Pub. Date: Apr. 24, 2025

(54) ENHANCED PACKAGING FOR FLIP-CHIP DEVICES

(71) Applicant: Qorvo US, Inc., Greensboro, NC (US)

(72) Inventor: Matthew Tyler Irvine, Garland, TX (US)

(21) Appl. No.: 18/908,361

(22) Filed: Oct. 7, 2024

Related U.S. Application Data
(60) Provisional application No. 63/591,548, filed on Oct. 19, 2023.

(51) Int. Cl. H01L 23/367; H01L 23/00; H01L 23/31; H01L 23/373; H01L 23/42; H01L 23/538; H01L 25/065

(52) U.S. Cl. CPC H01L 23/3675; H01L 23/3736; H01L 23/42; H01L 24/16; H01L 24/32; H01L 24/73; H01L 25/0655; H01L 23/3107; H01L 23/5385; H01L 2224/16225; H01L 2224/32225; H01L 2224/73253

(57) ABSTRACT

An integrated circuit package is provided. According to some aspects, the integrated circuit package includes a plurality of devices comprising a flip-chip having an active side. The package further includes a base layer configured to electrically interconnect the plurality of devices, wherein the active side of the flip-chip is positioned opposite the base layer and is electrically connected to the base layer; and a thermally conductive layer positioned so that the plurality of devices are located between the base layer and the thermally conductive layer, wherein the flip-chip is thermally connected to the thermally conductive layer. In some embodiments, a coefficient of thermal expansion (CTE) of the thermally conductive layer is approximately the same as the base layer, and wherein the CTE of the flip-chip is not approximately the same as the CTE of the thermally conductive layer or the CTE of the base layer.

### CROSS-REFERENCE TO RELATED APPLICATIONS

The present application claims priority to and the benefit of U.S. Provisional Patent Application No. 63/591,548, filed Oct. 19, 2023, the entirety of which is hereby incorporated by reference.

### TECHNICAL FIELD

The present disclosure relates generally to providing packaged flip-chip devices, and, more particularly, to systems and methods of packaging for thermal management of flip-chip devices, including enhanced flip-chip packages.

### BACKGROUND

Controlling the temperature of electronic devices is becoming increasingly useful as the size of the devices decreases and/or more functionality is being implemented in these devices. Problems with controlling the temperature are particularly acute for microsystems that include at least one flip-chip device, sometimes referred to as a device or integrated circuit or die that uses flip-chip interconnect technology. In some contexts, a flip-chip device generally refers to a chip or die or integrated circuit in which the active side is electrically coupled to a substrate or printed circuit board (PCB) via an array of conducting elements, such as pillars or solder bumps/balls. Flip-chip connections can increase the number of connections that can be made for a given die size and can also improve electrical performance.

One drawback to flip-chip devices is that it can be more difficult to control the temperature and channel heat away from the devices, since the primary heat path through the interconnects is limited. An example flip-chip device is a power amplifier, such as a radio frequency (RF) power amplifier as part of a wireless communication transmitter. Cooling of power amplifier modules is becoming increasingly useful, with an increasing desire for power amplifier solutions that send signal and heat in opposite directions on the module. This can be particularly relevant in base station applications where the signal from the power amplifier in a wireless transmitter application may be directed to an antenna array while the heat is directed to a heat sink on an opposite side of the power amplifier.

In addition, device packages are being designed to accommodate an increasing number of devices, to satisfy a desire for more complex electrical systems provided within a given package. For example, in communications applications, there may be a desire to include filters, beamformers, power amplifiers, and other components within a single package. In addition to more heat being generated, there is also a greater risk of warping of the package, due to mismatches in coefficients of thermal expansion (CTE) among different materials in the package and also from the increases in package size.

Thus, there remains a need for effective ways to direct heat out of flip-chip packages while maintaining structural integrity of the packages.

### SUMMARY

Embodiments of the present disclosure include systems, devices, and methods of packaging for improved thermal management of flip-chip devices, including enhanced flip-chip packages, while maintaining structural integrity of the packages.

In an exemplary aspect, an integrated circuit package is provided. The integrated circuit package includes a plurality of devices including a flip-chip having an active side. In some aspects, the package further includes a base layer configured to electrically interconnect the plurality of devices, wherein the active side of the flip-chip is positioned opposite the base layer and is electrically connected to the base layer. In some aspects, the package further includes a thermally conductive layer positioned so that the plurality of devices are located between the base layer and the thermally conductive layer, wherein the flip-chip is thermally connected to the thermally conductive layer, wherein a coefficient of thermal expansion (CTE) of the thermally conductive layer is approximately the same as the base layer, and wherein the CTE of the flip-chip is not approximately the same as the CTE of the thermally conductive layer or the CTE of the base layer.

In an exemplary aspect, a heterogeneous integrated circuit package for wireless communications is provided. In some aspects, the package includes a plurality of devices including a flip-chip having an active side, wherein the flip-chip is a radio frequency power amplifier. In some aspects, the package further includes a first layer configured to electrically interconnect the plurality of devices, wherein the active side is positioned opposite the first layer and is electrically connected to the first layer; and a second layer positioned so that the plurality of devices are located between the first layer and the second layer, wherein the flip-chip is thermally connected to the second layer. In some aspects, a CTE of the first layer is a first value that results in a substantially planar thermally conducive layer in all operating conditions, and the CTE of the flip-chip is not substantially the same as either the CTE of the first layer or the CTE of the second layer.

In an exemplary aspect, system for wireless communications is provided. In some aspects, the system includes a plurality of devices including a flip-chip having a first side and a second side, wherein the first side is configured to receive an input signal and transmit an output signal. In some aspects, the system further includes a first laminate layer configured to electrically interconnect the plurality of devices and transmit the input signal and receive the output signal, wherein the first side is positioned opposite the first laminate layer; and a second laminate layer positioned so that the plurality of devices are located between the first laminate layer and the second laminate layer, wherein the flip-chip is thermally connected to the second laminate layer via the second side. In some aspects, a CTE of the first laminate layer is approximately the same as the second laminate layer, and the CTE of the flip-chip is not the same as the CTE of the first laminate layer or the CTE of the second laminate layer.

Additional aspects, features, and advantages of the present disclosure will become apparent from the following detailed description.

### BRIEF DESCRIPTION OF THE DRAWINGS

The accompanying drawing figures incorporated in and forming a part of this specification illustrate several aspects of the disclosure, and together with the description, serve to explain the principles of the disclosure.

FIG. 1 is a cross-sectional view of a representative package, according to some aspects of the present disclosure.

FIG. 2 illustrates a top view of a package, according to some aspects of the present disclosure.

FIG. 3 is a cross-sectional view of another representative package, according to some aspects of the present disclosure.

FIG. 4 illustrates an exemplary cellular base station, according to some aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

Exemplary embodiments of integrated circuit device packages and systems are presented herein. Some packages include first and second laminate layers with multiple devices sandwiched in between. Some of the devices can be flip-chip devices, which can be considered as chips or integrated circuits or dies and which can be radio frequency power amplifiers that generate significant heat. One laminate layer (e.g., a first laminate layer) is used primarily for electrically interconnecting the various devices, and another laminate layer (e.g., a second laminate layer) is used primarily for thermal connectivity and dissipation of heat. In some embodiments, there are regions in the second laminate layer for heat dissipation that include heat dissipation regions, such as heat slugs, and these regions create channels for heat flow from respective devices. A combination of materials in the second laminate layer, in regions other than heat dissipation regions, are tuned to have a coefficient of thermal expansion to provide a substantially flat package under all operating conditions and/or to protect the package from flexural damage, even for heterogeneous integration of different chips or integrated circuits within the package.

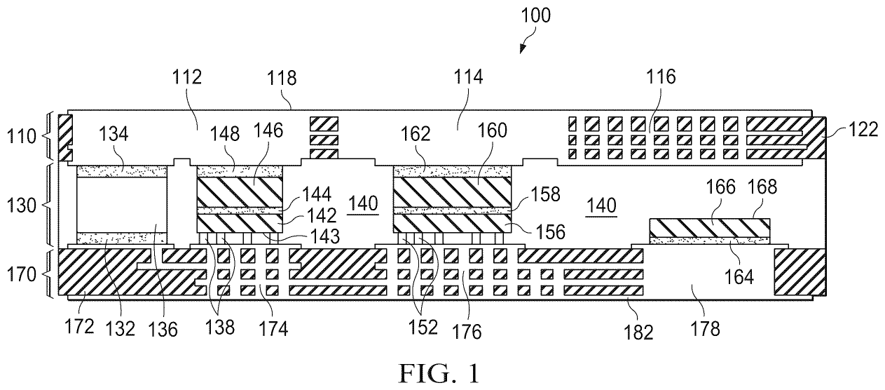

FIG. 1 is a cross-sectional view of a representative package 100, according to aspects of the present disclosure. The package 100 illustrates an exemplary solution for channeling, or spreading, or facilitating the dissipation of, heat from the package. As shown, the package 100 includes three layers, a top laminate layer 110 (or first layer), a bottom, or base, laminate layer 170 (or second layer), and an intermediate, or device, layer 130. The terms “top” and “bottom” as used herein are used to refer to relative positions of package features as oriented in a figure, and, as would be understood in the art, do not imply any particular orientation of the package 100 in use. According to one embodiment, the package 100 includes embedded devices 142, 156, and 166. As shown, one or more of the embedded devices may be flip-chips, such as devices 142 and 156, and one or more of the embedded devices may be top-side active devices, such as device 166, which may be a GaN device.

The flip-chips 142 and 156 are electrically connected to layer 170 via conductive pillars, some of which are labeled as 138 and 152, respectively. A side or surface of the flip- chips 142 and 156 that are electrically connected to layer 170 may be referred to as an active side. For example, an active side of flip-chip 142 is labeled as 143. The active side of flip-chips 142 and 156, such as active side 143, receives input signals from layer 170 and transmits output signals to layer 170. In some embodiments, for each flip-chip, the associated pillars or solder balls form an array of interconnects, such as a ball grid array, which provides an electrical connection from the flip-chips to layer 170. Pillars made of copper or any suitable conductive material may be used, or any suitable solder may be used in lieu or pillars. The flip-chip 142 is directly connected via a connection layer 144 to a spacer 146, which is directly connected to layer 110 via another connection layer 148. The connection layers 144 and 148 may be any suitable solder or epoxy material, as understood in the art. Likewise, flip-chip 156 is connected via a connection layer 158 to a spacer 160, which is connected to layer 110 via another connection layer 162. The connection layers 158 and 162 may be a suitable solder or epoxy material, as understood in the art. In other embodiments, a spacer may not be needed. For example, flip-chip 142 could be sufficiently taller/thicker such that it can be connected directly to layer 110 via layer 144 with spacer 146 and connection layer 148 removed or not included.

In an embodiment, the package 100 further includes a thermal shunt 136, sandwiched between top layer 110 and bottom layer 170 via connection layers 132 and 134, respectively. The thermal shunt 136 can provide additional thermal spreading, support, or additional signal routing and may be made of ceramic or other materials, such as alumina or aluminum nitride. In some embodiments, the thermal shunt 136 is not included in the package 100, and in some embodiments, more than one thermal shunt is included in the package 100. Additional “dummy” structures (not shown) may be included in the package 100 to increase structural integrity as well. Further, a thermal insulator can be introduced into the package 100 in the same manner as the shunt 136 if there is a need to isolate heat somewhere in the package 100.

In an embodiment, the package further includes device 166, having a top side 168 that is active. In other words, the signal inputs and outputs to device 166 are via top side 168. In some embodiments, the device 166 is electrically connected to layer 170 via wire bonds (not shown) connected on the top side 168.

The spacers 146 and 160 are coupled to the backsides of devices 142 and 156, respectively, to allow heat to pass from the backsides to the layer 110. A connection layer 164 thermally connects the bottom surface of device 166 to layer 170. Layer 170 further comprises a heat spreading region 178 to facilitate the flow and dissipation of heat from device 166. Heat spreading region 178 may be made of copper or another good thermal conductor.

At least one of the flip-chips 142 and 156 may be a power amplifier. For example, a signal to be amplified may be received from layer 170, by either flip-chip 142 or 156, and the amplified signal may be transmitted to layer 170. Further, the package 100 may represent a system used for wireless communication in a base station in a cellular network. For example, the package 100 may include at least one power amplifier, at least one filter (low-pass, radio frequency filter, etc.), at least one low noise amplifier, and/or at least one beamformer, and various components or devices may be interconnected through layer 170 to one or more antennas, such as an antenna array, located on or near the bottom surface 182 of package 100. As is understood, power amplifiers are a significant source of heat in certain applications. Any additional devices in package 100 may be implemented as flip-chips or as top-side active devices without departing from the inventive aspects of this disclosure.

As shown in FIG. 1, the voids or spaces between the previously described structures in layer 130 can be filled using an electronics molding compound. Some of the voids are represented as 140 in FIG. 1. During manufacture, after the package is assembled, molding compound can be flowed into the air cavity created between layers 110 and 170, thus filling the air cavity. Alternatively, glass or some other material can be used in layer 130, with holes cut into the material to accommodate the structures, such as flip-chips 142 and 156. The molding compound or other material disposed in voids 140 around the various devices adds structural strength and protection of the package.

In example embodiments, the average CTE of layer 170 may be between 9 and 16 parts per million per ° C. (referred to herein as PPM), and the average CTE of layer 110 may be between 9 and 16 PPM. In these embodiments, the CTE of the electronics molding compound in spaces 140 may be in a wide range (e.g., between 2 PPM and 50 PPM), and the CTE of various chips, such as flip-chips 142 and 156, may be between 2 and 5 PPM, which is typical of commercial devices such as radio frequency power amplifiers. These ranges of CTE are exemplary and are not intended to be limiting.

In some embodiments, the bottom laminate 170 provides conductive interconnections between various devices, some of which are represented at 174 and 176, with the interconnections surrounded by dielectric material 172 (also denoted by patterning). In some embodiments, the layer 170 is a substrate providing conductive interconnections among various chips or devices, according to the desired application.

This disclosure recognizes that the CTE of a laminate layer in an integrated circuit package may be tuned so that the package does not deform significantly over a full range of operating temperatures or conditions, which may be a range of temperatures from below 0° C. to over 200° C. For example, the CTE of the layer 110 is tuned to result in a substantially flat or planar package 100 under all operating temperatures, e.g., the top surface 118 remains substantially planar or flat. In other words, the layer 110 provides a sufficient degree of matching the CTE of the layer 170 to protect the package from flexural damage, even for heterogeneous integration of different chips or integrated circuits, such as chips 142, 156, and 166, into a single package. For example, the CTE of layer 110 may tuned to within 1%, 5%, 10%, 15%, etc. of the CTE of layer 170, or the CTE of layer 110 may be tuned to be approximately equal to the CTE of layer 170.

In the exemplary embodiment of FIG. 1, the layer 110 includes a combination of thermally conductive material and dielectric, with the combination having a CTE tuned appropriately. For example, layer 110 includes heat spreading regions 112 and 114 that are thermally coupled via spacers to flip-chips 142 and 156, respectively. For example, flip-chip 142 (156) may be directly attached to a heat spreading region 112 (114), or may be directly connected to a heat spreading region 112 (114) via one or more spacers and connection layers as shown in FIG. 1. The thermally conductive material in layer 110 may be made of copper or any other thermally conductive material. The layer 110 may also include various vias and patterns of thermally conductive material, such as 116, surrounded by dielectric material 122 (also denoted by a pattern), to tune the CTE of layer 110. The dielectric material 122 can be the same or different material than the dielectric material 172. Thus, regions of the layer 110, other than heat spreading regions 112 and 114, can be CTE-tuned as desired using a balance of conductor and dielectric.

The top laminate 110 can incorporate metal slugs, such as 112 and 114, also known as heat spreaders, that can greatly increase thermal spreading, but the rest of the laminate can be metal-balanced to tune the CTE to match the CTE of the bottom laminate 170. This can remove the reliability concerns of using a purely metal top-side spreader. The top laminate 110 can also incorporate additional signal or direct current routing as needed, adding an additional benefit of the package 100. For example, one or more vias or signal traces, implemented such as 116, may be used for signal routing and interconnection.

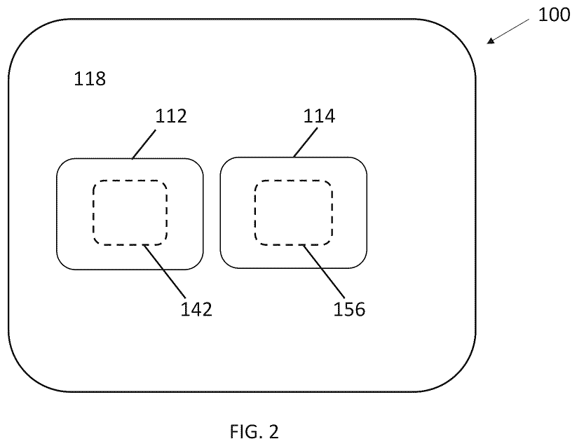

FIG. 2 illustrates a top view of package 100, showing top surface 118, according to some aspects of the present disclosure. As shown, the cross-sectional area of heat spreading regions 112 and 114 is larger than the cross-sectional area of corresponding flip-chips 142 and 156, respectively, so that heat can be dissipated more effectively.

Returning to FIG. 1, the thermally conductive regions 112 and 114 may be made of the same material, such as copper or another thermally conductive material. The layer 110 provides a thermally conductive channel for heat from devices 142 and 156 to dissipate through a top surface 118, in a direction opposite of signal propagation from these devices 142 and 156 into layer 170. As such, the layer 110 may also be referred to as a thermally conductive layer or substrate. Both of the layers 110 and 170 may be considered substrates. The layer 170 may also be referred to as a base layer or base substrate.

In some embodiments, the devices in layer 130 and also the layer 130 itself are not constrained to be substantially the same CTE as layers 110 or 170. For example, in one embodiment, the CTE values of flip-chip devices 142 and 156 are significantly different than the CTE values of layers 110 and 170. One benefit of this design flexibility is that active devices, such as flip-chips 142 and 156, may be designed according to their intended purposes, placed within layer 130, and electrically connected to layer 170, without regard for the thermal conductivity of these devices. The reduced stress from the balanced stack in package 100 may allow for the presence of an air cavity under an active flip-chip die, such as flip-chip 156. This can be accomplished by creating a dam around the die before the laminate lid 110 is attached.

Instead of the CTE-tuned layer 110, a full metal layer may be used instead for even greater potential heat dissipation. However, one problem with using such an approach is that the CTE of the metal could put significant stress on the attachment between the chip stacks and the layer (which may also be referred to as a lid). This would degrade the thermal performance of the attachment layers and could cause the package 100 itself to fall apart. In some experiments using packages having at least one power amplifier, a package, such as package 100, with no lid reached a junction temperature of 211° C., whereas the package having a laminate lid was over 30° C. cooler at the junction, at 179° C. The use of a full metal lid reduced the junction temperature even further, but a full metal lid causes the problems with stresses and package deformities described above.

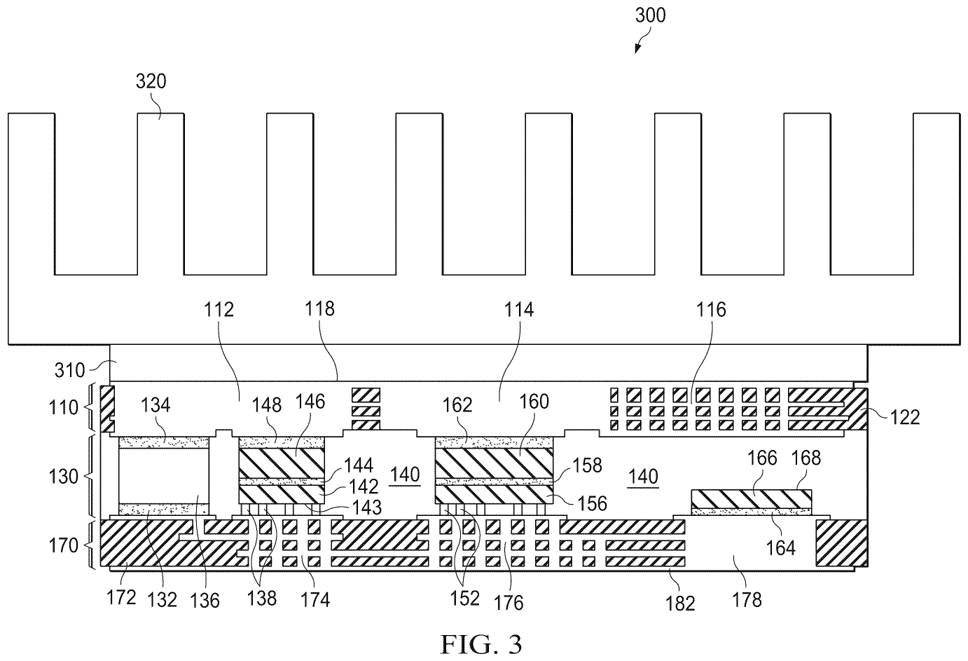

FIG. 3 illustrates a cross-sectional view of another representative package 200, according to aspects of the present disclosure. Package 200 includes the package 100 of FIG. 1, and further includes thermal interface material (TIM) 310 and chassis 320 as shown. Typical materials used for the TIM 310 include thermal greases, thermal pads, phase change materials, and thermal pastes having metallic particles, or any other suitable material, as is understood in the art. Typical materials used for the chassis 320 are metals, such as copper, aluminum, composites, or any other suitable metal or material, as is understood in the art. The package 200 may be used in a cellular base station application, for example, in which the chassis 320 further assists with heat dissipation. In an example embodiment, the chassis 320 is located on the outside of a module mounted on a cellular base station. Because of the relatively poor performance of TIM materials that may be used in various application, such as a wireless communication application having power amplifier(s), the additional thermal spreading of heat using a CTE-tuned laminate lid 110 before it passes into the TIM 310 can provide a significant drop in thermal rise. Heat spreaders, such as 112 and 114, in the laminate lid 110 allow for an increased footprint that reduces the heat flux passing into the TIM 310 attaching the module to the next-level-assembly.

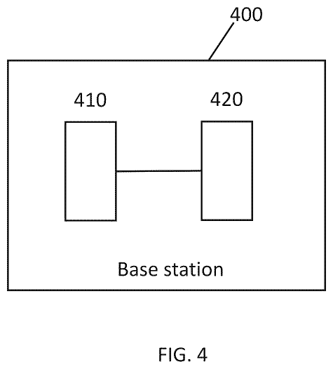

FIG. 4 illustrates an exemplary cellular base station 400, according to aspects of the present disclosure. In an embodiment, the base station 400 includes a package 410 coupled to an antenna 420. In an embodiment, the package 410 may be package 100 or 300 as described above, and the antenna 420 may include one or more radio frequency antennas or an antenna array. The cellular base station 400 may be configured for operation according to one or more cellular standards, such as fourth generation (4G) or fifth generation (5G) cellular standards. In the base station 400, the package 410 may include a flip-chip RF power amplifier and other components, such as filter(s) and beamformer(s) for providing wireless communication capability in the cellular base station 400. The base station 400 may provide wireless communication capability, for example, in one or more frequencies between 50 MHz and 60 GHz.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

what is claimed is:

1. An integrated circuit package comprising:
a plurality of devices comprising a flip-chip having an active side;
a base layer configured to electrically interconnect the plurality of devices, wherein the active side of the flip-chip is positioned opposite the base layer and is electrically connected to the base layer; and
a thermally conductive layer positioned so that the plurality of devices are located between the base layer and the thermally conductive layer, wherein the flip-chip is thermally connected to the thermally conductive layer,
wherein a coefficient of thermal expansion (CTE) of the thermally conductive layer is approximately the same as the base layer, and wherein the CTE of the flip-chip is not approximately the same as the CTE of the thermally conductive layer or the CTE of the base layer.

2. The integrated circuit package of claim 1, further comprising a spacer, wherein the flip-chip is thermally connected to the thermally conductive layer via the spacer, wherein the thermally conductive layer comprises a heat spreading region, and wherein the spacer is connected to the heat spreading region via a connection layer.

3. The integrated circuit package of claim 2, further comprising:
a second flip-chip having a second active side; and
a second spacer,
wherein the second active side is positioned opposite the base layer and is electrically connected to the base layer, and wherein the second flip-chip is thermally connected to the thermally conductive layer via the second spacer.

4. The integrated circuit package of claim 1, wherein the flip-chip is a radio frequency power amplifier.

5. The integrated circuit package of claim 1, further comprising a plurality of solder balls arranged as a ball grid array, wherein the ball grid array electrically connects the active side of the flip-chip to the base layer.

6. The integrated circuit package of claim 2, further comprising a second spacer, wherein:
the thermally conductive layer comprises a first heat spreading region and a second heat spreading region;
the first heat spreading region is attached to the spacer via a first connection layer; and
the second heat spreading region is attached to the second spacer via a second connection layer.

7. The integrated circuit package of claim 6, wherein the thermally conductive layer comprises a dielectric material and a metal, and where the first heat spreading region and the second heat spreading region are made of the metal.

8. The integrated circuit package of claim 1, further comprising molding compound surrounding the flip-chip.

9. The integrated circuit package of claim 3, further comprising a top-side active device having a first side and a second side,
wherein the base layer further comprises a heat spreading region, wherein the first side is electrically connected to the base layer, and wherein the second side is thermally connected to the heat spreading region.

10. The integrated circuit package of claim 1, wherein the CTE value of the flip-chip is in a range of about 2 to 5 parts per million per ° C., and the CTE value of the thermally conductive layer is in a range of about 9 to 16 parts per million per ° C.

11. A heterogeneous integrated circuit package for wireless communications comprising:
a plurality of devices comprising a flip-chip having an active side, wherein the flip-chip is a radio frequency power amplifier;
a first layer configured to electrically interconnect the plurality of devices, wherein the active side is positioned opposite the first layer and is electrically connected to the first layer; and
a second layer positioned so that the plurality of devices are located between the first layer and the second layer, wherein the flip-chip is thermally connected to the second layer,
wherein a coefficient of thermal expansion (CTE) of the first layer is a first value that results in a substantially planar thermally conducive layer in all operating conditions, and wherein the CTE of the flip-chip is not substantially the same as either the CTE of the first layer or the CTE of the second layer.

12. The heterogeneous integrated circuit package of claim 11, wherein the plurality of devices further comprises a filter, and wherein the heterogeneous integrated circuit package is configured to connect to an antenna array.

13. The heterogeneous integrated circuit package of claim 12, further comprising a thermal shunt sandwiched between the first layer and the second layer, wherein the thermal shunt is configured to direct heat from the first layer to the second layer.

14. The heterogeneous integrated circuit package of claim 11, wherein the CTE value of the flip-chip is in a range of about 2 to 5 parts per million per ° C., and the CTE value of the first layer is in a range of about 9 to 16 parts per million per ° C.

15. The heterogeneous integrated circuit package of claim 11, wherein the first value is approximately the same as the CTE of the second layer.

16. A system for wireless communications comprising:
a plurality of devices comprising a flip-chip having a first side and a second side, wherein the first side is configured to receive an input signal and transmit an output signal;
a first laminate layer configured to electrically interconnect the plurality of devices and transmit the input signal and receive the output signal, wherein the first side is positioned opposite the first laminate layer; and
a second laminate layer positioned so that the plurality of devices are located between the first laminate layer and the second laminate layer, wherein the flip-chip is thermally connected to the second laminate layer via the second side,
wherein a coefficient of thermal expansion (CTE) of the first laminate layer is approximately the same as the second laminate layer, and wherein the CTE of the flip-chip is not the same as the CTE of the first laminate layer or the CTE of the second laminate layer.

17. The system of claim 16, further comprising a thermal shunt sandwiched between the first laminate layer and the second laminate layer, wherein the thermal shunt is configured to direct heat from the first laminate layer to the second laminate layer.

18. The system of claim 16, wherein the CTE value of the flip-chip is in a range of about 2 to 5 parts per million per ° C., and the CTE value of the first laminate layer is in a range of about 9 to 16 parts per million per ° C.

19. The system of claim 16, wherein the second laminate layer comprises a heat spreader, and wherein the heat spreader is attached to the flip-chip.

20. The system of claim 19, wherein:
the plurality of devices further comprises a second flip-chip;
the second flip-chip comprises a second active side;
the second laminate layer further comprises a second heat spreader;
the second active side is positioned opposite of, and is electrically connected to, the first laminate layer; and
the second heat spreader is attached to the second flip-chip.
